(19) United States
(12) Patent Application Publication
(10) Pub. No.: US 2015/0188021 A1
(43) Pub. Date: Jul. 2, 2015

(54) APPARATUS AND METHOD OF DRIVING PIEZOELECTRIC ACTUATOR, AND PIEZOELECTRIC SYSTEM USING THE SAME

(71) Applicant: SAMSUNG ELECTRO-MECHANICS CO., LTD., SUWON-SI (KR)

(72) Inventors: Joo Yul Ko, Suwon-Si (KR); Chan Woo Park, Suwon-Si (KR)

(73) Assignee: SAMSUNG ELECTRO-MECHANICS CO., LTD., SUWON-SI (KR)

(21) Appl. No.: 14/246,874

(22) Filed: Apr. 7, 2014

(30) Foreign Application Priority Data
Dec. 30, 2013 (KR) 10-2013-0166834

(51) Int. Cl. H01L 41/04; H01L 41/09

(52) U.S. Cl. CPC H01L 41/042; H01L 41/09

(57) ABSTRACT

An apparatus for driving a piezoelectric actuator may include a waveform synthesizing unit outputting a digital value using waveform information input from the outside, an amplifying unit amplifying an analog value corresponding to the digital value, a voltage supplying unit generating an amplified voltage by amplifying an external input voltage and providing the amplified voltage to the amplifying unit, and a stabilization controlling unit determining whether the amplified voltage is stabilized and controlling the waveform synthesizing unit so as to output the digital value in the case in which the amplified voltage is stabilized.

### CROSS-REFERENCE TO RELATED APPLICATIONS

This application claims the benefit of Korean Patent Application No. 10-2013-0166834 filed on Dec. 30, 2013, with the Korean Intellectual Property Office, the disclosure of which is incorporated herein by reference.

### BACKGROUND

The present disclosure relates to an apparatus and a method of driving a piezoelectric actuator, and a piezoelectric system using the same.

As an interest in user interfaces has increased and related technology has been developed, reactive technology for user input has become a key factor in designing user interfaces in a terminal.

An early reaction technology of providing simple vibrations in response to user inputs for providing intuitive data input confirmation to users has been used.

Recently, since providing reactions or vibrations to data input to users has emerged as an important factor in device design, the provision of vibrations to users with ever greater precision has become a major issue. In order to satisfy the above-mentioned issue, a technical transition from touch reaction technology according to the related art, based on a motor driving technology, to haptic technology, capable of providing various types of reactive feedback, has been conducted.

Haptic technology, which refers to an overall system transferring tactile feedback to a user, may transfer tactile feedback to a user by vibrating a vibration element to thereby transfer physical impulses to the user. The haptic technology as described above merely provides a reaction for simply identifying the input in early days. However, in order to provide haptic feedback to users for precise controlling, it is required to provide users with various types of reactive feedback.

To this end, it is required to provide haptic technology able to provide rich vibration patterns by using various vibrational frequencies. In order to satisfy demand for haptic technology, piezoelectric actuators formed of a ceramic material have been recently used. Piezoelectric actuators have faster response speeds, less noise, and higher resonance bandwidths than existing liner resonance actuators and vibration motors including magnets. Therefore, such a piezoelectric actuator may variously provide fine and three-dimensional vibrations.

Such a piezoelectric actuator needs to be precisely driven. In order to perform precise drive of the piezoelectric actuator, a stable voltage for generating a driving signal needs to be provided. Particularly, a piezoelectric actuator used in a low voltage device, such as a mobile terminal or the like, generates the driving signal by using a boosted voltage.

Therefore, when the driving signal is generated before the boosting of the voltage is performed or in a state in which the boosting of the voltage is not stably performed, distortion is generated in the driving signal, such that it is difficult to precisely drive the piezoelectric actuator.

Therefore, in order to solve the above-mentioned problem, the driving signal has traditionally been generated after waiting for a predetermined period or longer, required to boost the voltage. However, according to the related art as described above, since it is necessary to wait the predetermined period or longer, reactivity may be delayed in the driving of the piezoelectric actuator, in addition to the problem that the distortion is still generated in the driving signal because the boosting of the voltage is not stably performed, even in a case in which the predetermined time has passed.

### SUMMARY

An exemplary embodiment in the present disclosure may provide an apparatus and a method of driving a piezoelectric actuator capable of accurately generating a driving signal by determining whether an amplified voltage is stabilized to thereby generate the driving signal, and a piezoelectric system using the same.

According to an exemplary embodiment in the present disclosure, an apparatus for driving a piezoelectric actuator may include: a waveform synthesizing unit outputting a digital value using waveform information input from the outside; an amplifying unit amplifying an analog value corresponding to the digital value; a voltage supplying unit generating an amplified voltage by amplifying an external input voltage and providing the amplified voltage to the amplifying unit; and a stabilization controlling unit determining whether the amplified voltage is stabilized and controlling the waveform synthesizing unit so as to output the digital value when the amplified voltage is stabilized.

The waveform synthesizing unit may output the digital value using a preset lookup table.

The waveform synthesizing unit may include: a waveform information storage storing waveform information; a lookup table storage storing the lookup table; and a controller providing a plurality of digital values included in the lookup table to a digital to analog converting unit in response to a control signal input from the stabilization controlling unit.

The waveform synthesizing unit may include: a waveform function generator outputting the digital value according to a preset equation; and a controller controlling the waveform function generator to be operated in response to a control signal input from the stabilization controlling unit.

The voltage supplying unit may include a boost converter boosting an external input voltage to output a driving voltage.

The stabilization controlling unit may determine that the amplified voltage is stabilized when a state in which the amplified voltage is equal to a preset threshold voltage or above is maintained for a predetermined period or longer.

The stabilization controlling unit may include: a hysteresis comparator receiving a preset threshold voltage and the amplified voltage; and a counter counting outputs of the hysteresis comparator.

The stabilization controlling unit may include: a hysteresis comparator receiving a preset threshold voltage and the amplified voltage; a glitch filter receiving outputs of the hysteresis comparator; and a counter counting outputs of the glitch filter.

According to an exemplary embodiment in the present disclosure, a piezoelectric system may include: an apparatus for driving a piezoelectric actuator generating an amplified voltage and generating a driving signal when the amplified voltage is in a stabilized state; and a piezoelectric device which is driven by receiving the driving signal.

The apparatus for driving the piezoelectric actuator may include: a waveform synthesizing unit outputting a predetermined digital value using waveform information input from the outside; an amplifying unit amplifying an analog value corresponding to the digital value to output the driving signal; a voltage supplying unit generating an amplified voltage by amplifying an external input voltage and providing the amplified voltage to the amplifying unit; and a stabilization controlling unit determining whether the amplified voltage is stabilized and controlling the waveform synthesizing unit so as to output the digital value when the amplified voltage is stabilized.

According to an exemplary embodiment in the present disclosure, a method of driving a piezoelectric actuator may include: generating an amplified voltage by amplifying an external input voltage; determining whether the amplified voltage is stabilized; outputting a digital waveform by using waveform information input from the outside when the amplified voltage is stabilized; and converting the digital waveform into an analog waveform and amplifying the analog waveform by using the amplified voltage.

The generating of the amplified voltage may include driving a boost converter boosting an external input voltage to output a driving voltage.

The determining of whether the amplified voltage is stabilized may include determining that the amplified voltage is stabilized when a state in which the amplified voltage is equal to a preset threshold voltage or above is maintained for a predetermined period or longer.

The determining of whether the amplified voltage is stabilized may include: performing a hysteresis comparison between a preset threshold voltage and the amplified voltage; and counting results of the hysteresis comparison and determining that the amplified voltage is in the stabilized state when the preset number or more of the results of the hysteresis comparison are counted.

The determining of whether the amplified voltage is stabilized may include: performing a hysteresis comparison between a preset threshold voltage and the amplified voltage; performing glitch filtering for results of the hysteresis comparison; and counting the glitch filtered results and determining that the amplified voltage is in the stabilized state when the preset number or more of the glitch filtered results are counted.

The outputting of the digital waveform may include outputting the digital value using a preset lookup table.

The outputting of the digital waveform may include outputting the digital value by executing a waveform function including a preset equation.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a graph illustrating a time relationship between a general amplified voltage and a driving signal;

FIG. 2 is a block diagram illustrating a system for driving a piezoelectric actuator according to an exemplary embodiment of the present disclosure;

FIG. 3 is a block diagram illustrating a stabilization controlling unit of FIG. 2 according to an exemplary embodiment of the present disclosure;

FIG. 4 is a block diagram illustrating a waveform synthesizing unit of FIG. 2 according to an exemplary embodiment of the present disclosure;

FIG. 5 is a block diagram illustrating a waveform synthesizing unit of FIG. 2 according to another exemplary embodiment of the present disclosure;

FIG. 6 is a graph illustrating a time relationship between a amplified voltage and a driving signal according to an exemplary embodiment of the present disclosure; and

FIG. 7 is a flow chart describing a method of driving a piezoelectric actuator according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

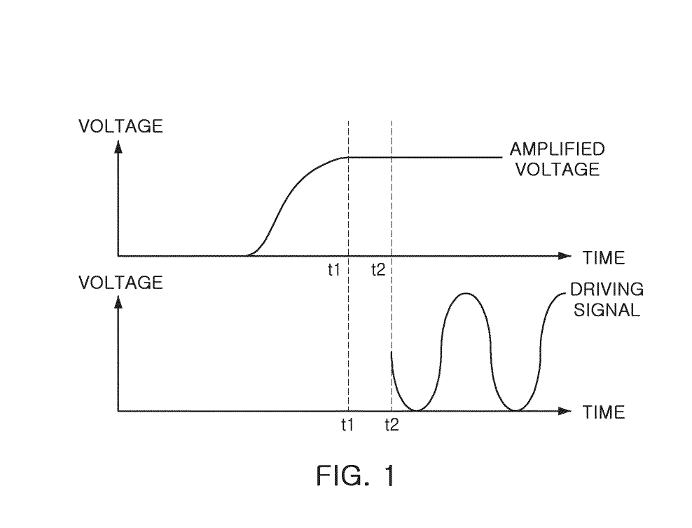

FIG. 1 is a graph illustrating a time relationship between a general amplified voltage and a driving signal.

As illustrated in FIG. 1, after a time t1 at which an amplified voltage is stably boosted, a driving signal may be generated. For example, the reason is that distortion may be generated in the driving signal due to the amplified voltage in the case in which the amplified voltage is not stable.

Therefore, in a general case, the driving signal may be generated at a time t2 that a time is further added to an approximation of the time t1 at which a boosting of a voltage is completed. For example, after the time sufficient to sufficiently boost the voltage is elapsed, the driving signal may be generated.

However, in this case, since the driving signal is not generated during the time from time t1 to the time t2, the generation of the driving signal may be delayed.

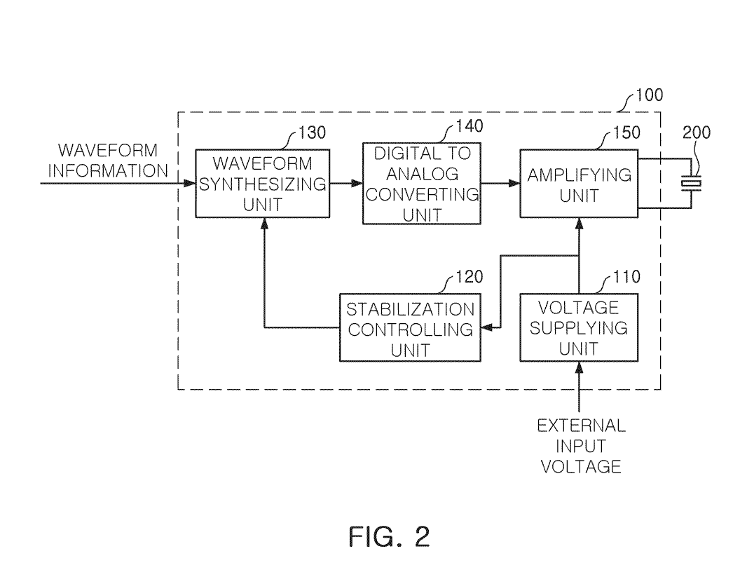

Hereinafter, various exemplary embodiments of the present disclosure will be described with reference to FIGS. 2 through 7.

FIG. 2 is a block diagram illustrating a system for driving a piezoelectric actuator according to an exemplary embodiment of the present disclosure.

The system for driving the piezoelectric actuator may include an apparatus 100 for driving a piezoelectric actuator and a piezoelectric device 200.

The piezoelectric device 200 may be driven by receiving the driving signal. The piezoelectric device 200 may be driven by receiving a pair of sine waves through a pair of input terminals.

The apparatus 100 for driving the piezoelectric actuator may generate an amplified voltage and may generate the driving signal in the case in which the amplified voltage is in a stabilized state.

The apparatus 100 for driving the piezoelectric actuator may include a voltage supplying unit 110, a stabilization controlling unit 120, a waveform synthesizing unit 130, a digital to analog converting unit 140, and an amplifying unit 150.

The voltage supplying unit 110 may amplify an external input voltage to generate an amplified voltage and may provide the amplified voltage to the amplifying unit 150.

The stabilization controlling unit 120 may check whether the amplified voltage is stabilized and may control the waveform synthesizing unit 130 to output a digital value in the case in which the amplified voltage is stabilized. When the waveform synthesizing unit 130 is operated in a state in which the amplified voltage is not stabilized, distortion may be generated in the driving signal.

According to an exemplary embodiment of the present disclosure, the stabilization controlling unit 120 may determine that the amplified voltage is stabilized when a state in which the amplified voltage is equal to a preset threshold voltage or above is maintained for a predetermined period or longer.

The waveform synthesizing unit 130 may output a predetermined digital value using waveform information input from the outside. Successive digital values output from the waveform synthesizing unit 130 may be converted into analog values corresponding to the digital values by the digital to analog converting unit 140. The analog value output from the digital to analog converting unit 140 may be amplified by the amplifying unit 150 to thereby become the driving signal.

According to an exemplary embodiment of the present disclosure, the voltage supplying unit 150 may include a boost converter boosting an external input voltage to thereby output a driving voltage.

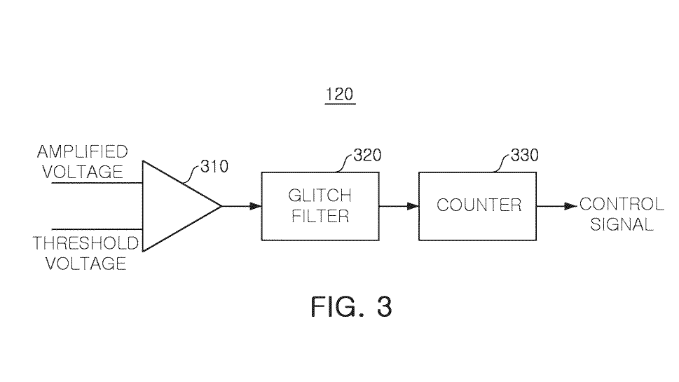

FIG. 3 is a block diagram illustrating a stabilization controlling unit of FIG. 2 according to an exemplary embodiment of the present disclosure.

According to an exemplary embodiment of the present disclosure, the stabilization controlling unit 120 may include a hysteresis comparator 310, a glitch filter 320, and a counter 330.

The hysteresis comparator 310 may receive the preset threshold voltage and the amplified voltage to thereby perform a hysteresis comparison.

The glitch filter 320 may receive an output from the hysteresis comparator 310 to thereby remove a clock noise.

The counter 330 may count outputs from the glitch filter 320. In the case in which the number of clocks counted by the counter 330 is a predetermined level or above, it may be determined that the amplified voltage is stabilized and a control signal instructing the waveform synthesization to start may be output.

According to another exemplary embodiment of the present disclosure, the stabilization controlling unit 120 may include a hysteresis comparator 310 and a counter 330. This exemplary embodiment of the present disclosure has a configuration in which the glitch filter 320 is removed from the exemplary embodiment of the present disclosure of FIG. 3, and the stabilization controlling unit 120 may be configured as in this exemplary embodiment of the present disclosure in the case in which occurrence probability of a clock noise is relatively low.

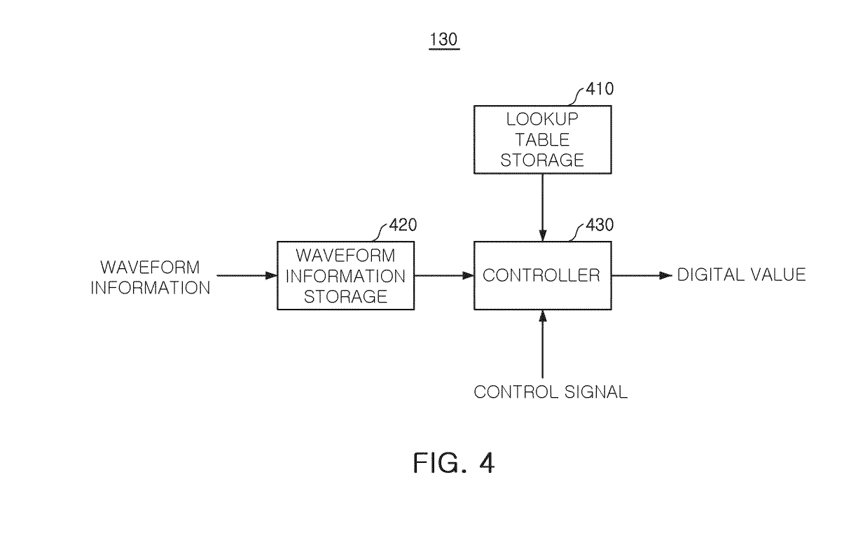

FIG. 4 is a block diagram illustrating a waveform synthesizing unit of FIG. 2 according to an exemplary embodiment of the present disclosure. An exemplary embodiment of the present disclosure illustrated in FIG. 4 relates to an example outputting the digital value using a preset lookup table.

Referring to FIG. 4, the waveform synthesizing unit 130 may include a lookup table storage 410, a waveform information storage 420, and a controller 430.

The lookup table storage 410 may store the preset lookup table and the waveform information storage 420 may store waveform information input from the outside. Here, waveform information may include information for at least one of a frequency, a cycle and an amplitude of the driving signal.

The controller 430 may provide a plurality of digital values included in the lookup table to the digital to analog converting unit 140 in response to the control signal input from the stabilization controlling unit 120. For example, when the controller 430 receives the control signal instructing the waveform synthesization to start from the stabilization controlling unit 120, the controller 430 may output the digital value using the lookup table.

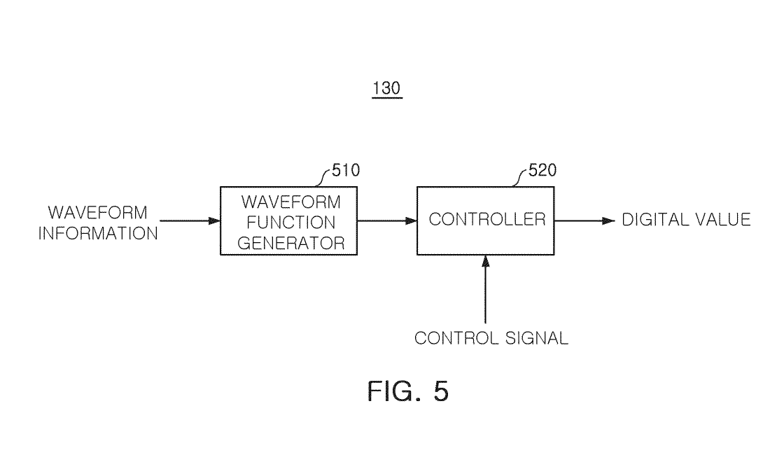

FIG. 5 is a block diagram illustrating a waveform synthesizing unit of FIG. 2 according to another exemplary embodiment of the present disclosure. Another exemplary embodiment of the present disclosure illustrated in FIG. 5 relates to an example outputting the digital value using a function.

Referring to FIG. 5, the waveform synthesizing unit 130 may include a waveform function generator 510 and a controller 520.

The waveform synthesizing unit 130 may output the digital value according to a preset equation. Here, the digital value output according to the preset equation may correspond to the digital value which is output using the lookup table of FIG. 4.

The controller 520 may control the waveform function generator 510 to be operated in response to the control signal input from the stabilization controlling unit 120.

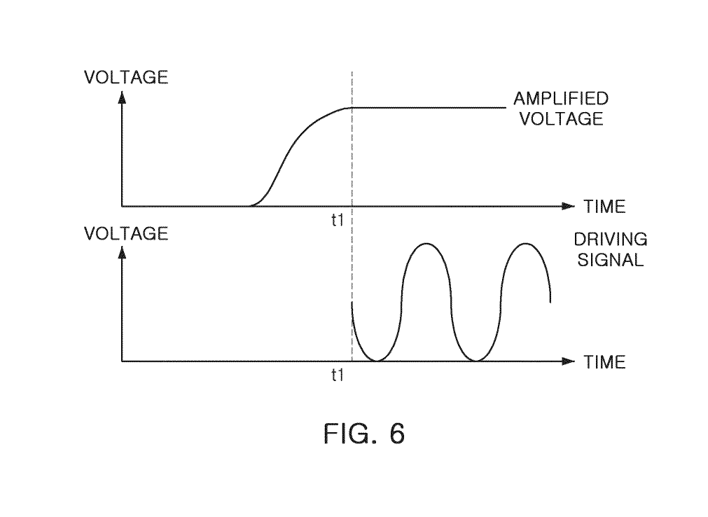

FIG. 6 is a graph illustrating a time relationship between an amplified voltage and a driving signal according to an exemplary embodiment of the present disclosure.

As illustrated in FIG. 6, according to an exemplary embodiment of the present disclosure, when the amplified voltage is normally boosted, the driving signal may be generated by determining whether the amplified voltage is normally boosted. In this case, since a start time of the generation of the driving signal and a completion time of the boosting of the amplified voltage are equal to each other or are very close to each other, the boosting does not affect the driving signal, such that distortion may be prevented.

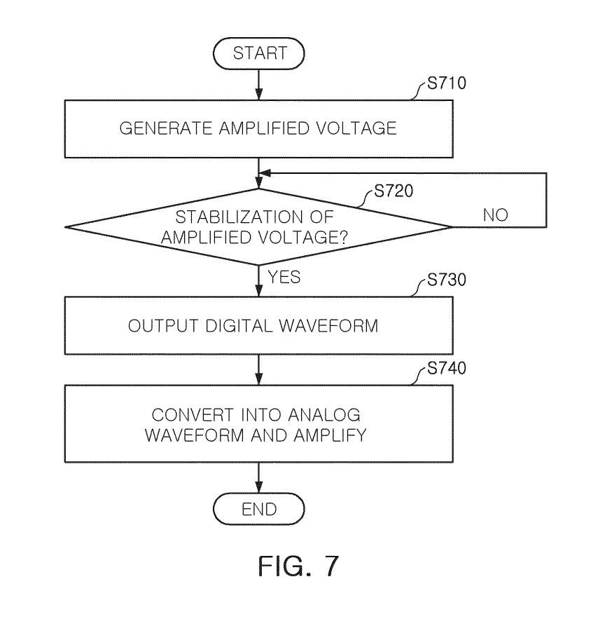

Hereinafter, a method of driving a piezoelectric actuator according to an exemplary embodiment of the present disclosure will be described with reference to FIG. 7. However, since the method of driving the piezoelectric actuator to be described below is performed in the apparatus for driving the piezoelectric actuator described above with reference to FIGS. 2 through 6, a description of content that is the same as or corresponds to the above described description will be omitted.

FIG. 7 is a flow chart describing a method of driving a piezoelectric actuator according to an exemplary embodiment of the present disclosure.

Referring to FIG. 7, the apparatus 100 for driving the piezoelectric actuator may generate the amplified voltage by amplifying the external input voltage (S710).

Next, the apparatus 100 for driving the piezoelectric actuator may check whether the amplified voltage is stabilized (S720).

For example, when the amplified voltage is stabilized (YES of S720), then a digital waveform may be output by using waveform information input from the outside (S730).

Meanwhile, when the amplified voltage is not stabilized (NO of S720), the determining of whether the amplified voltage is stabilized may be re-performed (S720).

Next, the apparatus 100 for driving the piezoelectric actuator may convert the digital waveform into an analog waveform and may amplify and output the analog waveform by using the amplified voltage (S740).

In an example of S710, the apparatus 100 for driving the piezoelectric actuator may drive the boost converter outputting the driving voltage by boosting the external input voltage.

In an example of S720, the apparatus 100 for driving the piezoelectric actuator may determine that the amplified voltage is stabilized when a state in which the amplified voltage is equal to a preset threshold voltage or above is maintained for a predetermined period or longer.

In an example of S720, the apparatus 100 for driving the piezoelectric actuator may perform a hysteresis comparison between the preset threshold voltage and the amplified voltage, may count results of the hysteresis comparison, and may determine that the amplified voltage is in the stabilized state in the case in which the preset number or more of the results of the hysteresis comparison are counted.

In an example of S720, the apparatus 100 for driving the piezoelectric actuator may perform the hysteresis comparison between the preset threshold voltage and the amplified voltage and may perform glitch filtering for the results of the hysteresis comparison. Next, the apparatus 100 for driving the piezoelectric actuator may count the glitch filtered results and may determine that the amplified voltage is in the stabilized state in the case in which the preset number or more of the glitch filtered results are counted.

In an example of S730, the apparatus 100 for driving the piezoelectric actuator may output the digital value using the preset lookup table.

In an example of S730, the apparatus 100 for driving the piezoelectric actuator may output the digital value by executing a waveform function including a preset equation.

As set forth above, according to exemplary embodiments of the present disclosure, the driving signal may be generated in the state in which the amplified voltage is stabilized by determining whether the amplified voltage is stabilized, such that the driving signal may be accurately generated and the piezoelectric actuator may be accurately driven.

While exemplary embodiments have been shown and described above, it will be apparent to those skilled in the art that modifications and variations could be made without departing from the spirit and scope of the present disclosure as defined by the appended claims.

What is claimed is:

1. An apparatus for driving a piezoelectric actuator, the apparatus comprising:
a waveform synthesizing unit outputting a digital value using waveform information input from the outside;
an amplifying unit amplifying an analog value corresponding to the digital value;
a voltage supplying unit generating an amplified voltage by amplifying an external input voltage and providing the amplified voltage to the amplifying unit; and
a stabilization controlling unit determining whether the amplified voltage is stabilized and controlling the waveform synthesizing unit so as to output the digital value when the amplified voltage is stabilized.

2. The apparatus of claim 1, wherein the waveform synthesizing unit outputs the digital value using a preset lookup table.

3. The apparatus of claim 2, wherein the waveform synthesizing unit includes:
a waveform information storage storing waveform information;
a lookup table storage storing the lookup table; and
a controller providing a plurality of digital values included in the lookup table to a digital to analog converting unit in response to a control signal input from the stabilization controlling unit.

4. The apparatus of claim 1, wherein the waveform synthesizing unit includes:
a waveform function generator outputting the digital value according to a preset equation; and
a controller controlling the waveform function generator to be operated in response to a control signal input from the stabilization controlling unit.

5. The apparatus of claim 1, wherein the voltage supplying unit includes a boost converter boosting an external input voltage to output a driving voltage.

6. The apparatus of claim 1, wherein the stabilization controlling unit determines that the amplified voltage is stabilized when a state in which the amplified voltage is equal to a preset threshold voltage or above is maintained for a predetermined period or longer.

7. The apparatus of claim 1, wherein the stabilization controlling unit includes:
a hysteresis comparator receiving a preset threshold voltage and the amplified voltage; and
a counter counting outputs of the hysteresis comparator.

8. The apparatus of claim 1, wherein the stabilization controlling unit includes:
a hysteresis comparator receiving a preset threshold voltage and the amplified voltage;
a glitch filter receiving outputs from the hysteresis comparator; and
a counter counting outputs from the glitch filter.

9. A piezoelectric system, comprising:
an apparatus for driving a piezoelectric actuator generating an amplified voltage and generating a driving signal when the amplified voltage is in a stabilized state; and
a piezoelectric device which is driven by receiving the driving signal.

10. The piezoelectric system of claim 9, wherein the apparatus for driving the piezoelectric actuator includes:
a waveform synthesizing unit outputting a predetermined digital value using waveform information input from the outside;
an amplifying unit amplifying an analog value corresponding to the digital value to output the driving signal;
a voltage supplying unit generating an amplified voltage by amplifying an external input voltage and providing the amplified voltage to the amplifying unit; and
a stabilization controlling unit determining whether the amplified voltage is stabilized and controlling the waveform synthesizing unit so as to output the digital value when the amplified voltage is stabilized.

11. A method of driving a piezoelectric actuator, the method comprising:
generating an amplified voltage by amplifying an external input voltage;
determining whether the amplified voltage is stabilized;
outputting a digital waveform by using waveform information input from the outside when the amplified voltage is stabilized; and
converting the digital waveform into an analog waveform and amplifying the analog waveform by using the amplified voltage.

12. The method of claim 11, wherein the generating of the amplified voltage includes driving a boost converter boosting an external input voltage to output a driving voltage.

13. The method of claim 11, wherein the determining of whether the amplified voltage is stabilized includes determining that the amplified voltage is stabilized when a state in which the amplified voltage is equal to a preset threshold voltage or above is maintained for a predetermined period or longer.

14. The method of claim 11, wherein the determining of whether the amplified voltage is stabilized includes:
performing a hysteresis comparison between a preset threshold voltage and the amplified voltage; and
counting results of the hysteresis comparison and determining that the amplified voltage is in the stabilized state when the preset number or more of the results of the hysteresis comparison are counted.

15. The method of claim 11, wherein the determining of whether the amplified voltage is stabilized includes:
performing a hysteresis comparison between a preset threshold voltage and the amplified voltage;
performing a glitch filtering for results of the hysteresis comparison; and
counting the glitch filtered results and determining that the amplified voltage is in the stabilized state when the preset number or more of the glitch filtered results are counted.

16. The method of claim 11, wherein the outputting of the digital waveform includes outputting the digital value using a preset lookup table.

17. The method of claim 11, wherein the outputting of the digital waveform includes outputting the digital value by executing a waveform function including a preset equation.
